(19) United States
(12) Patent Application Publication
(10) Pub. No.: US 2022/0011949 A1
(43) Pub. Date: Jan. 13, 2022

(54) SAFEKEEPING DEVICE, SAFEKEEPING SYSTEM, CONTROL METHOD, AND NON-TRANSITORY COMPUTER-READABLE RECORDING MEDIUM

(71) Applicant: NEC Corporation, Tokyo (JP)

(72) Inventor: Shunsuke GOTO, Tokyo (JP)

(73) Assignee: NEC Corporation, Tokyo (JP)

(21) Appl. No.: 17/368,505

(22) Filed: Jul. 6, 2021

(30) Foreign Application Priority Data
Jul. 7, 2020 (JP) 2020-117367

(51) Int. Cl. G06F 3/06; G07C 9/00; G06F 11/14

(52) U.S. Cl. CPC G06F 3/0622; G07C 9/00174; G06F 11/1451; G07C 2009/00634; G06F 3/0655; G06F 3/0679; G06F 3/0625

(57) ABSTRACT

A safekeeping device includes a case configured to house a storage device including a nonvolatile memory, and a processor configured to control electric power so that the electric power is supplied to the nonvolatile memory at a predetermined timing.

### INCORPORATION BY REFERENCE

This application is based upon and claims the benefit of priority from Japanese patent application No. 2020-117367, filed on Jul. 7, 2020, the disclosure of which is incorporated herein in its entirety by reference.

### TECHNICAL FIELD

The present invention relates to a safekeeping device, a safekeeping system, a control method, and a non-transitory computer-readable recording medium.

### BACKGROUND ART

A storage device is used in various devices or systems.

Published Japanese Translation No. 2012-509521 of the PCT International Publication discloses a technique regarding recovery of data recorded in a solid state drive (SSD) as the related art.

Japanese Unexamined Patent Application, First Publication No. 2007-065984 discloses a technique regarding the backup of data recorded in a storage device as the related art.

### SUMMARY

Incidentally, in a storage device, such as an SSD, including a nonvolatile memory, in a case where a time for which electric power is not supplied exceeds a certain time, there is a possibility that stored data is changed or lost.

For this reason, there is a need for a technique capable of maintaining data while the storage device including the nonvolatile memory is kept safe.

An example object of the invention is to provide a safekeeping device, a safekeeping system, a control method, and a non-transitory computer-readable recording medium capable of solving the above-described problem.

A safekeeping device according to an example aspect of the invention includes a case configured to house a storage device that includes a nonvolatile memory, and a processor configured to control electric power so that the electric power is supplied to the nonvolatile memory at a predetermined timing.

A safekeeping system according to an example aspect of the invention includes the above-described safekeeping device, and the storage device.

A control method performed by a safekeeping device that includes a case, the case being configured to house a storage device that includes a nonvolatile memory, includes controlling electric power so that the electric power is supplied to the nonvolatile memory at a predetermined timing.

A non-transitory computer-readable recording medium stores a program for a safekeeping device including a case, the case being configured to house a storage device including a nonvolatile memory. The program causes the safekeeping device to execute controlling electric power so that the electric power is supplied to the nonvolatile memory at a predetermined timing.

### BRIEF DESCRIPTION OF THE DRAWINGS

FIG. 1 is a diagram showing an example of a configuration of a safekeeping system according to a first example embodiment of the invention.

FIG. 2 is a diagram showing an example of a configuration of a safekeeping device according to the first example embodiment of the invention.

FIG. 3 is a diagram showing an example of a processing flow of the safekeeping system according to the first example embodiment of the invention.

FIG. 4 is a diagram showing another example of the configuration of the safekeeping device according to the first example embodiment of the invention.

FIG. 5 is a diagram showing an example of a configuration of a safekeeping device according to a second example embodiment of the invention.

FIG. 6 is a diagram showing an example of a processing flow of a safekeeping system according to the second example embodiment of the invention.

FIG. 7 is a diagram showing an example of a configuration of a safekeeping device according to a third example embodiment of the invention.

FIG. 8 is a diagram showing an example of a data table in the third example embodiment of the invention.

FIG. 9 is a diagram showing an example of a processing flow of a safekeeping system according to a fourth example embodiment of the invention.

FIG. 10 is a diagram showing an example of a safekeeping device with a minimum configuration according to an example embodiment of the invention.

FIG. 11 is a diagram showing an example of a processing flow of the safekeeping device with a minimum configuration according to the example embodiment of the invention.

FIG. 12 is a schematic block diagram showing a configuration of a computer according to at least one example embodiment.

### EXAMPLE EMBODIMENT

Hereinafter, example embodiments will be described in detail referring to the drawings.

### First Example Embodiment

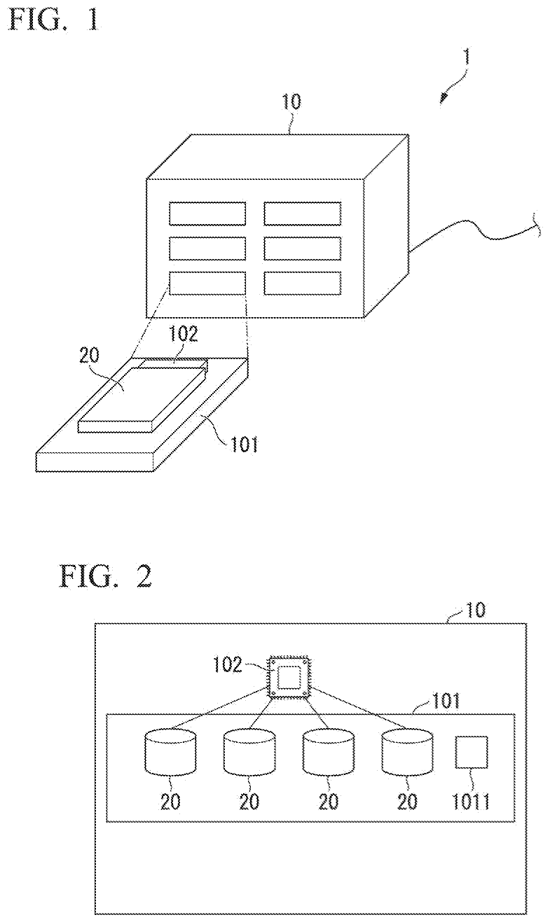

A safekeeping system 1 according to a first example embodiment of the invention is a system capable of safekeeping a solid state drive (SSD) for a long period while preventing data from being erased. As shown in FIG. 1, the safekeeping system 1 includes a safekeeping device 10 (an example of housing means) and an SSD 20.

As shown in FIGS. 1 and 2, the safekeeping device 10 includes a safekeeping stand 101 and a controller 102 (an example of control means, an example of backup processing means, an example of storage area decision means, an example of recovery means, and an example of initialization means). A safekeeping cabinet is an example of the safekeeping device 10.

The safekeeping stand 101 is a stand for placing the SSD 20 when the SSD 20 is housed and kept safe in the safekeeping device 10. The safekeeping stand 101 includes a power feed means (a power supply) 1011.

The power feed means 1011 supplies electric power to the SSD 20 under the control of the controller 102.

The power feed means 1011 is, for example, a means for supplying electric power from a power supply to the SSD 20 using a wire including a connector connectable to the SSD 20, or the like. The power feed means 1011 is, for example, a means for supplying electric power from a power supply to the SSD 20 using a wireless power feed technique.

The controller 102 controls electric power to be supplied to the SSD 20 at a predetermined timing. For example, the controller 102 brings the power feed means 1011 into an on state at a predetermined timing from a state in which the power feed means 1011 is controlled to an off state. In a case where the power feed means 1011 is brought into the on state, electric power is supplied from the power supply to the SSD 20 by the wire or wirelessly.

The predetermined timing is, for example, any timing in a period during which, in the SSD 20 in a state in which electric power is not supplied, data is normally stored before data is changed or lost. The predetermined timing is, for example, a timing at which the SSD 20 is housed in the safekeeping device 10.

For example, the standard of Joint Electron Device Engineering Council (JEDEC) defines that, even though electric power is not supplied, the SSD maintains data for three months or more under an environment in which the ambient temperature is 40 degrees. That is, in a case where electric power is not supplied, the SSD is likely to lose data in three months under an environment that the ambient temperature is 40 degrees. For example, in a case of the SSD that is likely to lose data in three months in this way, the predetermined timing is any timing in a period from when supply of electric power to the SSD is stopped to when data is lost after three months.

Note that the three months is a minimum period satisfying the standard of JEDEC, a manufacturer of an SSD may provide an SSD that does not lose data over a longer period than the three months. The ambient temperature in an actual safekeeping place is not always 40 degrees. For this reason, the predetermined timing may be decided in consideration of a type of an SSD (for example, a manufacturer of an SSD) that is actually kept safe, an actual ambient temperature of an SSD in the safekeeping device, or the like.

The SSD 20 is an example of a storage device including a nonvolatile memory. The SSD 20 has a refresh function. The refresh function applies a predetermined voltage to the nonvolatile memory to change the state of the SSD from a state in which electric power is not supplied to the SSD and the amount of electric charge configuring data is changed to a state in which the amount of electric charge is returned to the original amount of electric charge before change and a storage time of data in the SSD is extended.

There is a possibility that the SSD 20 should be kept safe for a long period while storing data in a case where the SSD 20 is used for backup, in a case where the SSD 20 is used as a principal part in manufacturing of a certain device, or the like.

Next, processing of the safekeeping system 1 according to the first embodiment of the invention will be described.

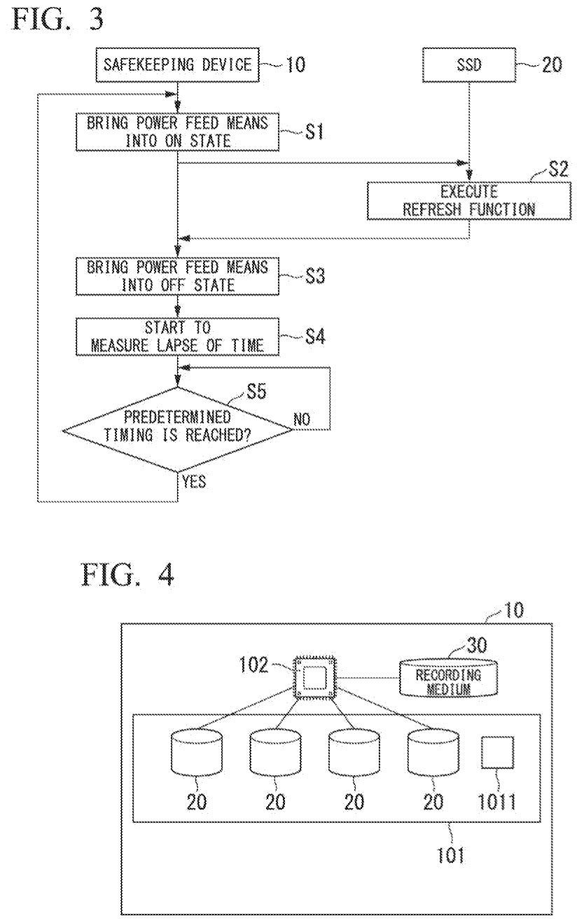

Here, processing of the safekeeping system 1 in a case of housing the SSD 20 in the safekeeping device 10 will be described in reference to the processing flow shown in FIG. 3.

A user places the SSD 20 on the safekeeping stand 101. In this case, when the power feed means 1011 supplies electric power to the SSD 20 using the wire, the user connects the SSD 20 to the connector or the like. When the power feed means 1011 supplies electric power to the SSD 20 wirelessly, the user places the SSD 20 within a power feed range of the safekeeping stand 101.

Then, the user places the safekeeping stand 101 on which the SSD 20 is placed, in the safekeeping device 10. The term “housing” may refer to a case where the user performs a predetermined operation (for example, an operation to press a button for instructing housing) and a mechanism provided in the safekeeping device 10 operates to house the safekeeping stand 101 in the safekeeping device 10. Alternatively, the term “housing” may refer to a case where the user manually houses the safekeeping stand 101 in the safekeeping device 10.

In a case where the safekeeping stand 101 is housed in the safekeeping device 10, the controller 102 controls the electric power to be supplied to the SSD 20.

Specifically, in a case where the safekeeping stand 101 is housed in the safekeeping device 10, the controller 102 brings the power feed means 1011 into the on state at the predetermined timing from a state in which the power feed means 1011 is controlled to the off state (Step S1). In a case where the power feed means 1011 is brought into the on state, electric power is supplied from the power supply to the SSD 20 by the wire or wirelessly.

In a case where electric power is supplied from the power supply, the SSD 20 executes the refresh function (Step S2). In a case where the SSD 20 completes the execution of the refresh function, the controller 102 brings the power feed means 1011 into the off state (Step S3). Then, the controller 102 starts to measure a lapse of time (Step S4).

The controller 102 determines whether or not a predetermined time elapses and the predetermined timing is reached (Step S5). In a case where determination is made that the predetermined timing is not reached (in Step S5, NO), the controller 102 returns to the processing of Step S5. In a case where determination is made that the predetermined timing is reached (in Step S5, YES), the controller 102 returns to the processing of Step S1.

The safekeeping system 1 repeats the processing of Steps S1 to S5 while the SSD 20 is housed in the safekeeping device 10.

In a case where a plurality of SSDs 20 are housed in the safekeeping device 10 at different timings, the safekeeping system 1 may record a lapse of time on each SSD 20, for example, in a recording medium 30 shown in FIG. 4 and may execute the processing of Steps S1 to S5. In this case, the recording medium 30 may be provided in the safekeeping device 10. Alternatively, the recording medium 30 may be provided outside the safekeeping device 10.

The safekeeping system 1 according to the first example embodiment of the invention has been described above. In the safekeeping system 1, the safekeeping device 10 houses the SSD 20 including the nonvolatile memory. The controller 102 supplies electric power to the SSD 20 at the predetermined timing.

In this manner, while the SSD 20 is housed in the safekeeping device 10, the safekeeping system 1 can execute the refresh function at the predetermined timing. As a result, while the SSD is kept safe, it is possible to reduce a possibility that data stored in the SSD is changed or lost. That is, while a storage device including a nonvolatile memory is kept safe, it is possible to reduce a possibility that data stored in the storage device is changed or lost.

### Second Example Embodiment

In the safekeeping system 1 according to the first example embodiment of the invention, a possibility that data of the SSD 20 is changed or lost before the refresh function is executed is low, but not 0%. A safekeeping system 1 according to a second example embodiment of the invention is a system capable of recovering original data even though data of the housed SSD 20 is changed or lost. The safekeeping system 1 according to the second example embodiment of the invention includes a safekeeping device 10 and an SSD 20.

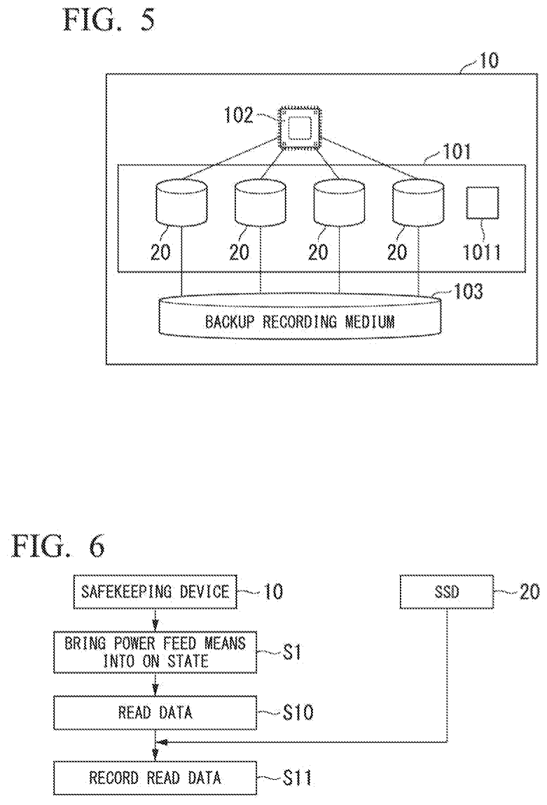

As shown in FIG. 5, the safekeeping device 10 includes a safekeeping stand 101, a controller 102, and a backup recording medium 103.

The controller 102 records backup data of data stored in the SSD 20 in the backup recording medium 103 in a case where the SSD 20 is housed in the safekeeping device 10, in addition to the processing that is executed by the controller 102 according to the first example embodiment of the invention.

For example, a storage area in the backup recording medium 103 is allocated in advance to each SSD 20. Then, the controller 102 records the backup data of the SSD 20 in the storage area allocated to the SSD 20.

The backup recording medium 103 stores the backup data of the SSD 20 under the control of the controller 102.

Next, processing of the safekeeping system 1 according to the second example embodiment of the invention will be described.

Here, processing of the safekeeping system 1 in a case of storing the backup data of the SSD 20 in the backup recording medium 103 will be described in reference to the processing flow shown in FIG. 6. It is desirable that processing of storing the backup data of the SSD 20 in the backup recording medium 103 is executed immediately after the SSD 20 is housed in the safekeeping device 10. Note that the processing may be executed at any time before data stored in the SSD 20 is changed or lost after the SSD 20 is housed in the safekeeping device 10.

In a case where the safekeeping stand 101 is housed in the safekeeping device 10, the controller 102 controls electric power to be supplied to the SSD 20.

Specifically, in a case where the safekeeping stand 101 is housed in the safekeeping device 10, the controller 102 brings the power feed means 1011 into the on state at the predetermined timing from a state in which the power feed means 1011 is controlled to the off state (Step S1). In a case where the power feed means 1011 is brought into the on state, electric power is supplied from the power supply to the SSD 20 by the wire or wirelessly.

In a case where electric power is supplied from the power supply to the SSD 20, the controller 102 reads data stored in the SSD 20 (Step S10). The controller 102 records the read data in the storage area of the backup recording medium 103 allocated in advance to the SSD 20 (Step S11). A hardware identification (ID) for identifying an individual may be given in advance to each SSD 20, and the controller 102 may specify each SSD 20 by reading the hardware ID.

The safekeeping system 1 according to the second example embodiment of the invention has been described above. In the safekeeping system 1, in a case where the SSD 20 is housed in the safekeeping device 10, the controller 102 records the backup data of data stored in the SSD 20 in the backup recording medium 103.

In this way, the safekeeping system 1 can recover original data of the SSD 20 even though data stored in the SSD 20 is changed or lost.

### Third Example Embodiment

In the safekeeping system 1 according to the first and second example embodiments of the invention, there is a possibility that the SSD 20 or the backup recording medium 103 is physically brought out or data may be read from the SSD 20 or the backup recording medium 103 in an unauthorized manner. A safekeeping system 1 according to a third example embodiment of the invention is a system capable of preventing leakage of data from the safekeeping system 1 compared to the safekeeping system 1 according to the first and second example embodiments of the invention. The safekeeping system 1 according to the third example embodiment of the invention includes a safekeeping device 10, an SSD 20, and a recording medium 30.

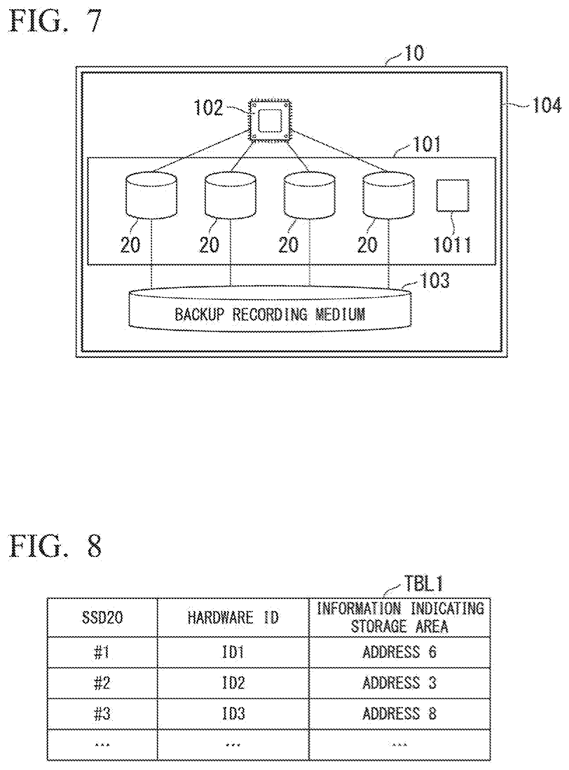

As shown in FIG. 7, the safekeeping device 10 includes a safekeeping stand 101, a controller 102, a backup recording medium 103, and a lock mechanism 104.

The lock mechanism 104 is a mechanism that prevents the SSD 20 or the backup recording medium 103 from being physically brought out from the safekeeping device 10. The lock mechanism 104 is, for example, a key or a shutter.

The controller 102 records backup data of data stored in the SSD 20 in the backup recording medium 103 in a case where the SSD 20 is housed in the safekeeping device 10, in addition to the processing that is executed by the controller 102 according to the first example embodiment of the invention.

Note that, in the second example embodiment of the invention, the backup data of each SSD 20 is stored in the storage area determined in advance, while, in the third example embodiment of the invention, the backup data of each SSD 20 is recorded in a storage area randomly decided by the controller 102 upon recording the backup data.

In a case where the backup data of the SSD 20 is recorded in the backup recording medium 103, the controller 102 initializes data of the SSD 20.

The recording medium 30 stores information indicating a correspondence relationship between the backup data of the SSD 20 and the storage area in the backup recording medium 103 randomly decided by the controller 102.

For example, as shown in FIG. 8, the information is a data table TBL1 in which the hardware identification (ID) unique to each SSD 20 is associated with information indicating the storage area in the backup recording medium 103. An address or a uniform resource locator (URL) is an example of information indicating the storage area in the backup recording medium 103.

Next, a method of preventing leakage of data from the safekeeping system 1 will be described. Here, four-step protection of a first step to a fourth step will be described from the viewpoint of protection of data.

The first step protection is protection by preventing the SSD 20 or the backup recording medium 103 from being physically brought out from the safekeeping device 10. This protection is realized, for example, by the lock mechanism 104 preventing the SSD 20 or the backup recording medium 103 from being physically brought out from the safekeeping device 10.

The second step protection is protection by keeping the storage area of the backup data of each SSD 20 secret. This protection is realized, for example, by the controller 102 randomly deciding the storage area of the backup data of each SSD 20.

The third step protection is protection by preventing data from being read even though each SSD 20 is physically brought out. This protection is realized, for example, by the controller 102 initializing data of the SSD 20 whose backup data is recorded in the backup recording medium 103.

The fourth step protection is protection by providing restriction when data of the SSD 20 is recovered using the backup data. This protection is realized, for example, by applying the recording medium 30 that stores information indicating the correspondence relationship between the backup data of the SSD 20 and the storage area in the backup recording medium 103 randomly decided by the controller 102, as a physical key for permitting recovery when data of the SSD 20 is recovered from the backup data.

For example, the recording medium 30 is a universal serial bus (USB) memory, and the USB memory is a physical key. Only in a case where the USB memory is physically inserted into the safekeeping device 10, and the safekeeping device 10 recognizes the USB memory, the backup data can be recovered based on information, stored in the USB memory, indicating the correspondence relationship between the backup data of the SSD 20 and the storage area in the backup recording medium 103 randomly decided by the controller 102.

The four-step protection of the first step to the fourth step is not necessarily conducted simultaneously, and one or more of the first step protection to the fourth step protection may be conducted.

The safekeeping system 1 according to the third example embodiment of the invention has been described above. The safekeeping system 1 conducts one or more of the four-step protection of the first step to the fourth step.

In this way, even though data stored in the SSD 20 is changed or lost, original data of the SSD 20 can be recovered.

### Fourth Example Embodiment

A safekeeping system 1 according to a fourth example embodiment of the invention is a system capable of performing backup of data of the SSD 20, executing the refresh function provided in the SSD 20, and recovering data of the SSD 20 using the backup data based on the techniques described on three example embodiments of the first example embodiment to the third example embodiment of the invention.

The safekeeping system 1 according to the fourth example embodiment of the invention includes a safekeeping device 10, an SSD 20, and a recording medium 30.

A controller 102 provided in the safekeeping device 10 determines whether or not the SSD 20 could execute the refresh function.

For example, the controller 102 determines that the refresh function could be executed in a case where a signal for notifying that the execution of the refresh function is completed is received from the SSD 20 within a predetermined time. The controller 102 determines that the refresh function could not be executed in a case where the signal for notifying that the execution of the refresh function is completed is not received from the SSD 20 within the predetermined time.

In a case where determination is made that the SSD 20 could execute the refresh function, the controller 102 completes the supply of electric power to the SSD 20 by bringing the power feed means 1011 into the off state.

In a case where determination is made that the SSD 20 could not execute the refresh function, the controller 102 initializes the SSD 20. The controller 102 recovers data of the SSD 20 using the backup data. Then, the controller 102 completes the supply of electric power to the SSD 20 by bringing the power feed means 1011 into the off state.

In a case where the SSD 20 could not be initialized, the controller 102 notifies the user of replacement of the SSD 20. In a case where the SSD 20 is replaced by the user, the controller 102 recovers data of the SSD 20 using the backup data. Then, the controller 102 completes the supply of electric power to the SSD 20 by bringing the power feed means 1011 into the off state.

Processing of the safekeeping system 1 according to the fourth example embodiment of the invention will be described.

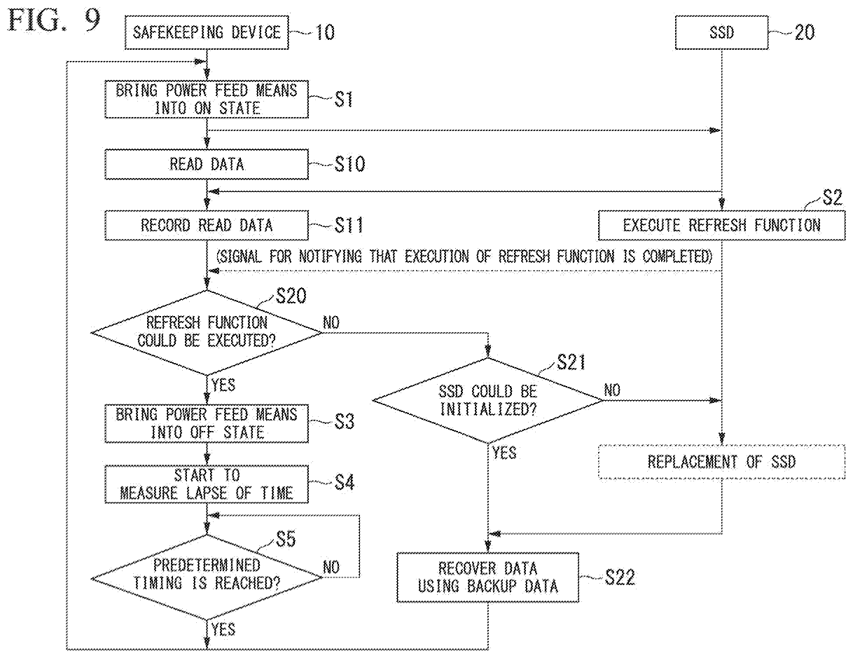

Here, processing of the safekeeping system 1 in a case of performing backup of data of the SSD 20, executing the refresh function provided in the SSD 20, and recovering data of the SSD 20 using the backup data will be described in reference to a processing flow shown in FIG. 9.

In the safekeeping system 1, the processing of Steps S1, S10, and S11 is executed. At this point of time, the backup data of the SSD 20 is recorded in the backup recording medium 103.

In the safekeeping system 1, in a case where the processing of Step S1 is executed, the execution of the processing of Step S2 is attempted in the SSD 20.

The controller 102 determines whether or not the SSD 20 could execute the refresh function (Step S20).

For example, the controller 102 determines that the refresh function could be executed in a case where a signal for notifying that the execution of the refresh function is completed is received from the SSD 20 within a predetermined time. The controller 102 determines that the refresh function could not be executed in a case where the signal for notifying that the execution of the refresh function is completed is not received from the SSD 20 within the predetermined time.

In a case where the controller 102 determines that the SSD 20 could execute the refresh function (in Step S20, YES), the safekeeping system 1 executes the processing of Steps S3, S4, and S5. The safekeeping system 1 returns to the processing of Step S1 in a case where determination is made to be Yes in Step S5.

In a case where determination is made that the SSD 20 could not execute the refresh function (in Step S20, NO), the controller 102 attempts to initialize the SSD 20. Then, the controller 102 determines whether or not the SSD 20 could be initialized (Step S21).

In a case where determination is made that the SSD 20 could be initialized (in Step S21, YES), the controller 102 recovers data of the SSD 20 using the backup data (Step S22). Then, the controller 102 returns to the processing of Step S1.

In a case where determination is made that the SSD 20 could not be initialized (in Step S21, NO), the controller 102 notifies the user of replacement of the SSD 20. In a case where the SSD 20 is replaced by the user, the controller 102 progresses to the processing of Step S22.

The safekeeping system 1 according to the fourth example embodiment of the invention has been described above. In the safekeeping system 1, the controller 102 determines whether or not the SSD 20 could execute the refresh function. In a case where determination is made that the SSD 20 could execute the refresh function, the controller 102 completes the supply of electric power to the SSD 20 by bringing the power feed means 1011 into the off state. In a case where determination is made that the SSD 20 could not execute the refresh function, the controller 102 initializes the SSD 20. The controller 102 recovers data of the SSD 20 using the backup data. Then, the controller 102 completes the supply of electric power to the SSD 20 by bringing the power feed means 1011 into the off state.

In a case where the SSD 20 could not be initialized, the controller 102 notifies the user of replacement of the SSD 20. In a case where the SSD 20 is replaced by the user, the controller 102 recovers data of the SSD 20 using the backup data. Then, the controller 102 completes the supply of electric power to the SSD 20 by bringing the power feed means 1011 into the off state.

In this way, even though data stored in the SSD 20 is changed or lost or even though failure occurs in the SSD 20, original data of the SSD 20 can be recovered.

A safekeeping device 10 with a minimum configuration according to an example embodiment of the invention will be described.

As shown in FIG. 10, the safekeeping device 10 with a minimum configuration according to the example embodiment of the invention includes housing means 10a and control means 10b.

The housing means 10a houses a storage device including a nonvolatile memory. The control means 10b supplies electric power of the nonvolatile memory at a predetermined timing.

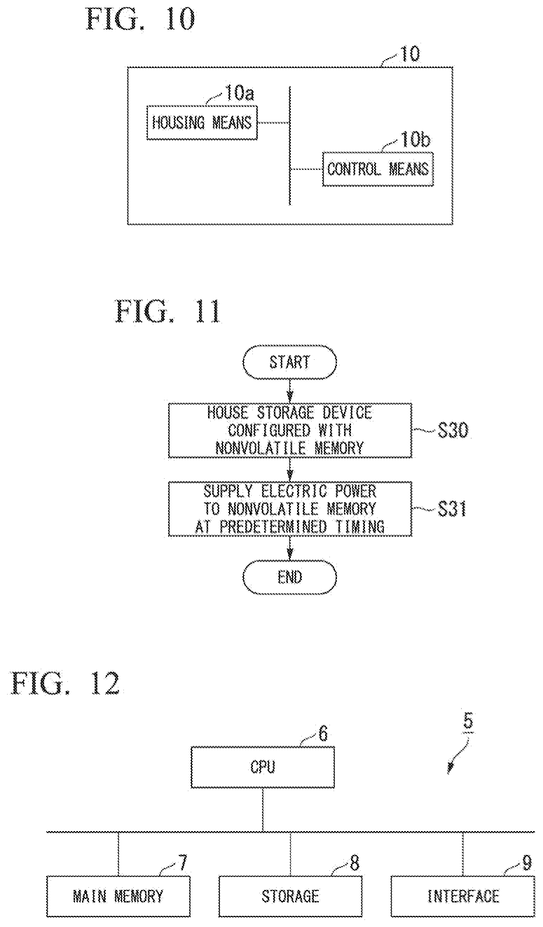

Next, processing of the safekeeping device 10 with a minimum configuration will be described in reference to FIG. 11.

The housing means 10a houses the storage device including the nonvolatile memory (Step S30).

The control means 10b supplies electric power to the nonvolatile memory at the predetermined timing (Step S31).

In this way, while the storage device including the nonvolatile memory is kept safe, it is possible to reduce a possibility that data stored in the storage device is changed or lost.

In another example embodiment of the invention, in a case where the safekeeping device 10 includes the recording medium 30 and the backup recording medium 103, the recording medium 30 and the backup recording medium 103 may be realized with one recording medium.

An order of the processing in the example embodiments of the invention may be changed in a range in which appropriate processing is executed.

Although the example embodiments of the invention have been described, the safekeeping system 1, the safekeeping device 10, the SSD 20, and other control devices described above may have a computer device. Then, the steps of the processing described above are stored in a computer readable recording medium in a form of a program, and the above-described processing is executed by the computer reading and executing the program. A specific example of the computer is described below.

FIG. 12 is a schematic block diagram showing the configuration of a computer according to at least one example embodiment.

As shown in FIG. 12, a computer 5 includes a CPU 6 (including a vector processor and a controller), a main memory 7, a storage 8, and an interface 9.

For example, each of the safekeeping system 1, the safekeeping device 10, the SSD 20, and other control devices described above is mounted in the computer 5. Then, an operation of each processing unit described above is stored in the storage 8 in the form of a program. The CPU 6 reads the program from the storage 8, loads the program in the main memory 7, and executes the above-described processing in compliance with the program. The CPU 6 secures a storage area corresponding to each storage unit described above in the main memory 7 in compliance with the program.

A hard disk drive (HDD), a solid state drive (SSD), a magnetic disk, a magneto-optical disk, a compact disc read only memory (CD-ROM), a digital versatile disc read only memory (DVD-ROM), and a semiconductor memory are examples of the storage 8. The storage 8 may be an internal medium connected directly to a bus of the computer 5 or may be an external medium connected to the computer 5 through the interface 9 or a communication line. In a case where the program is distributed to the computer 5 through the communication line, the computer 5 that receives the distribution may loads the program in the main memory 7 and may execute the above-described processing. In at least one example embodiment, the storage 8 is a non-transitory tangible recording medium.

The above-described program may realize a part of the above-described functions. The above-described program may be a file, called a differential file (differential program), capable of realizing the above-described functions in combination with a program recorded in advance in a computer device.

Although several example embodiments of the invention have been described, the example embodiments are merely examples and do not limit the scope of the invention. Various additions, omissions, substitutions, and alterations may be made to the example embodiments without departing from the spirit and scope of the invention.

An example advantage according to the invention is to reduce a possibility that data stored in the storage device is changed or lost while a storage device including a nonvolatile memory is kept safe.

While the invention has been particularly shown and described with reference to example embodiments thereof, the invention is not limited these embodiments. It will be understood by those of ordinary skill in the art that various changes in form and details may be made therein without departing from the spirit and scope of the present invention as defined by the claims.

What is claimed is:

1. A safekeeping device comprising:
a case configured to house a storage device that includes a nonvolatile memory; and
a processor configured to control electric power so that the electric power is supplied to the nonvolatile memory at a predetermined timing.

2. The safekeeping device according to claim 1,
wherein the predetermined timing is a timing in a period from when the case houses the storage device to when data of the storage device is changed or lost.

3. The safekeeping device according to claim 1,
wherein the processor is configured to record backup data of data stored in the storage device in a recording medium.

4. The safekeeping device according to claim 3,
wherein the processor is configured to randomly decide a storage area where the processor records the backup data in the recording medium.

5. The safekeeping device according to claim 4,
wherein the processor is configured to recover the data of the storage device from the backup data using a recording medium storing information regarding the storage area randomly decided by the processor as a physical key.

6. The safekeeping device according to claim 3,
wherein the processor is configured to initialize the data stored in the storage device in a case where the processor records the backup data.

7. The safekeeping device according to claim 1, further comprising:
a lock mechanism configured to prevent the storage device from being brought out.

8. A safekeeping system comprising:
the safekeeping device according to claim 1; and
the storage device.

9. A control method performed by a safekeeping device that includes a case, the case being configured to house a storage device including a nonvolatile memory, the control method comprising:
controlling electric power so that the electric power is supplied to the nonvolatile memory at a predetermined timing.

10. A non-transitory computer-readable recording medium storing a program for a safekeeping device that includes a case, the case being configured to house a storage device including a nonvolatile memory, the program causing the safekeeping device to execute:
controlling electric power so that the electric power is supplied to the nonvolatile memory at a predetermined timing.
